(19) United States
(12) Patent Application Publication
(10) Pub. No.: US 2023/0335663 A1
(43) Pub. Date: Oct. 19, 2023

(54) BACK-CONTACT SOLAR CELL, AND PRODUCTION THEREOF

(71) Applicant: EnPV GmbH, Karlsruhe (DE)

(72) Inventor: Erik HOFFMANN, Stuttgart (DE)

(21) Appl. No.: 18/028,088

(22) PCT Filed: Dec. 3, 2021
(86) PCT No.: PCT/EP2021/084193

§ 371 Date: Mar. 23, 2023

(30) Foreign Application Priority Data
Dec. 4, 2020 (DE) 10 2020 132 245.3

(51) Int. Cl. H01L 31/0735; H01L 31/0224; H01L 31/0236; H01L 21/02; H01L 21/225; H01L 21/268; H01L 21/306; H01L 31/0216

(52) U.S. Cl. CPC H01L 31/0735; H01L 31/022441; H01L 31/02363; H01L 21/02208; H01L 21/2256; H01L 21/268; H01L 21/30617; H01L 31/02167

(57) ABSTRACT

The invention relates to a method for producing a back-contact solar cell (10), and to a back-contact solar cell (10) comprising a semiconductor substrate (12), in particular a silicon wafer, comprising a front side (16) and a back side (14), the solar cell (10) comprising electrodes (36) of a first polarity and electrodes (38) of a second polarity on the back side, characterized in that that the electrodes (36) of the first polarity are located on a highly doped silicon layer (20) of the first polarity, the highly doped silicon layer (20) being located on a first passivation layer (18) located on the semiconductor substrate, and the electrodes (38) of the second polarity directly electrically and mechanically contacting the semiconductor substrate (12) via highly doped base regions (30) of the second polarity of the semiconductor substrate (12).

### CROSS-REFERENCE TO RELATED APPLICATIONS

This application is a national phase entry of PCT Application No. PCT/EP2021/084193, filed on Dec. 3, 2021, which claims priority to and the benefit of German Patent Application No. 10 2020 132 245.3, filed on Dec. 4, 2020, the disclosure of which are incorporated herein by reference in its entirety.

### DESCRIPTION

The invention relates to a solar cell and a method of producing a solar cell.

As is known, solar cells serve as photovoltaic elements for converting light into electrical energy. Charge carrier pairs which are generated in a semiconductor substrate during absorption of light are separated at the transition between an emitter region, which has a first doping type, e.g., n-type or p-type, for generating a first polarity, and a base region which has an opposite doping type for generating an opposite polarity. The charge carrier pairs generated and separated in this way can be supplied to an external circuit via emitter contacts, which contact the emitter region, and base contacts, which contact the base region.

Solar cells are known in which contacts of one polarity are arranged on the front side and contacts of the opposite polarity are arranged on the back side. The side facing the sun is referred to as the front side; the back side accordingly refers to the side facing away. In order to minimize losses resulting from shadowing due to the contacts arranged on the front side, and thus to increase efficiency, back-contact solar cells have been developed in which both contact types, i.e., the emitter contacts and the base contacts, are arranged on the back side of the semiconductor substrate.

Back-contact solar cells are known, for example, from US 2020/279968 A1, US 2014/096821 A1, US 2014/338747 A1, CN 209 087 883 U and US 2017/117433 A1.

Electrodes of the two polarities are arranged side-by-side on the back side of the solar cell. The charge carriers generated must thus also flow laterally in the solar cell. In order to minimize the resistance losses due to this lateral current flow and to prevent the free charge carriers from recombining before they reach the electrodes, the electrodes of the two polarities should lie as close together as possible. Since the electrodes are connected to either p- or n-type silicon, depending on the polarity, the pn junctions are also as close together as possible. The pn-junctions, fine, comb-like structures having a resolution below 500 μm, can be realized, for example, by means of laser irradiation. In this process, a pulsed laser beam drives two different dopants, e.g., boron and phosphorus, locally into the silicon by melting the surface in a temporally and locally separated manner, and produces either a high p-type or n-type doping, depending on the dopant. This is disclosed, for example, in DE 10 2013 219 564 A1. Such fine structures allow for low internal series resistances and efficiencies η of up to η=24%. Higher efficiencies are substantially limited by recombination mechanisms in the base and also on the highly doped contacted and non-contacted surfaces. The recombination in the base is dependent on the wafer quality and can be influenced only slightly in the further manufacturing process of the solar cell. The recombination at the highly doped n- and p-type surfaces is limited in the non-contacted region with good surface passivation, such as with amorphous hydrogenated silicon, by Auger recombination, which increases with the dopant concentration in the silicon. In the contacted region, the silicon is in contact with a metal, which results in high interfacial recombination. In the solar cell process, the Auger recombination at the non-contacted surfaces can be reduced if as little dopant as possible is located in the silicon there, while the interfacial recombination at the metal/silicon contacts can be reduced by a contact surface that is as small as possible. However, a simple reduction of the dopant and the contact surfaces results in an increase in the series resistance, which then becomes the limiting factor for the efficiency.

For this reason, passivated or also selective contacts are used, for example known from DE 10 2013 219 564 A1 or WO 2014/100004 A1. In this case, the electrodes are not electrically connected directly to the crystalline base, but are separated by a thin tunnel oxide which passivates the silicon surface, but at the same time is so thin that the electrons can tunnel through the oxide, from the semiconductor into the electrode or from the electrode into the semiconductor, depending on the polarity. In order to excite the electrons to tunnel, there must be an electric field at the tunnel oxide. The electric field can be generated by a highly doped n- or p-type silicon, on the tunnel oxide. Since the doping of this silicon above the tunnel oxide leads to band bending in the silicon base below the tunnel oxide, a higher doping of the silicon base is no longer necessary. At the highly doped n-type silicon, only electrons pass through the tunnel oxide, also referred to as an electron flow, while only what is known as a hole flow occurs at the highly doped p-type silicon: Electrons enter the silicon base from the highly doped p-type silicon. The metal electrodes themselves are still in electrical and mechanical contact only with the highly doped n- or p-type silicon above the tunnel oxide. The selectivity of the highly doped silicon regions in combination with the tunnel oxide ensures, depending on the doping, the transport of almost exclusively one type of charge carrier at the metal/silicon contact surfaces, and minimizes the interfacial recombination. The structure presented further reduces the Auger recombination at the surface of the silicon base to the tunnel oxide, since no high doping for the pn junction or the ohmic contact with the base is required at this interface. Back-contact solar cells having passivated contacts have hitherto reached a record efficiency of η=26.7%. However, the production of such cells has hitherto been very complicated, since the two differently doped selective contacts can only be applied using various complex masking and structuring steps. In this case, a high precision and fine resolution of the masking/structuring must be ensured. The spacing of the selective contacts may not be too large, and should not exceed the diffusion length of the free charge carriers and also not lead to an increase in the internal series resistance due to the lateral current flow in the base.

These disadvantages are overcome by a solar cell according to the invention and a method according to the invention for producing such a solar cell. At the same time, the method according to the invention enables industrial production having low process costs.

According to the invention, a back-contact solar cell according to claim one is proposed. The back-contact solar cell comprises a semiconductor substrate, in particular a silicon wafer, comprising a front side and a back side, the solar cell comprising, on the back side, electrodes of a first polarity and electrodes of a second polarity, it is proposed that the electrodes of the first polarity be arranged on a highly doped silicon layer of the first polarity, the highly doped silicon layer being arranged on a first passivation layer arranged on the semiconductor substrate, and the electrodes of the second polarity directly electrically and mechanically contacting the semiconductor substrate via highly doped base regions of the second polarity, of the semiconductor substrate.

It is therefore proposed that a different contacting concept be used for the electrodes of the first polarity and for the electrodes of the second polarity, such that both contacting concepts are combined in the case of the back-contact solar cell proposed according to the invention. For the electrodes of the first polarity, it is proposed that these contact the highly doped silicon layer, which is deposited on a passivation layer, also referred to as a tunnel layer. For the electrodes of the second polarity, it is proposed that these directly contact the semiconductor substrate. This requires masking and demasking during production.

It is provided that the highly doped base regions of the second polarity be formed within doped base regions of the second polarity on the back side of the solar cell, a dopant concentration in the highly doped base regions being higher than a dopant concentration in the doped base regions, and the doping concentration in the highly doped base regions being higher than a dopant concentration of a doped region on the front side of the solar cell. The doped base regions on the back side have a dopant concentration on the surface of 1×1017 cm-3 to 1×1019 cm-3. The doping on the entire front side can also have a dopant concentration on the surface of 1×1017 cm-3 to 1×1019 cm-3. The dopant concentration of the highly doped base regions for the base contact, on the surface, is preferably above a dopant concentration of 2×1019 cm-3.

According to one embodiment, it is provided for a second passivation layer to be arranged on surface regions of the back side which are not contacted by the electrodes of the first polarity and not by the electrodes of the second polarity. In this case, the second passivation layer is thicker than the first passivation layer. The region between two electrodes of different polarities comprises regions in which the second passivation layer is arranged and regions in which a layer stack comprising the first and the second passivation layer is arranged.

The surface of the solar cell according to the invention thus comprises the following differently doped regions:
a highly doped polycrystalline silicon layer of the first polarity on the back side of the solar cell on the first passivation layer arranged on the semiconductor substrate, the dopant concentration of the highly doped polycrystalline silicon layer being higher than the dopant concentration of the base;
doped monocrystalline base regions of the second polarity on the back side, the dopant concentration of the doped base regions being higher than the dopant concentration of the base;
highly doped monocrystalline base regions of the second polarity within the doped base regions on the back side, the dopant concentration of these highly doped base regions being higher than the dopant concentration of the base and the dopant concentration of the doped base regions.
a doped monocrystalline surface of a first or second polarity on the entire front side, the dopant concentration of the doped surface being higher than the dopant concentration of the base.

Further embodiments relate to a method for producing a back-contact solar cell according to the embodiments described above.

A semiconductor substrate of the solar cell comprises an, in particular polished or textured, back side, and an, in particular textured, front side. The texturing is carried out, for example, by a wet chemical solution.

A first passivation layer, in particular comprising silicon dioxide, is applied on a surface of the back side and/or on a surface of the front side. The first passivation layer has, for example, a thickness of preferably at most 4 nm. The first passivation layer is produced, for example, in a thermal or wet-chemical process or by deposition.

According to one embodiment, the method further comprises a step of depositing an, in particular full-surface, highly doped silicon layer of a first polarity on the first passivation layer on the back side and/or on the front side. The deposition of the highly doped silicon layer of the first polarity can take place, for example, by means of plasma-enhanced chemical vapor deposition, PECVD, atmospheric chemical vapor deposition, APCVD, low-pressure chemical vapor deposition, LPCVD, or cathode sputtering. The highly doped silicon layer of the first polarity has a thickness of approximately 50 nm to 400 nm. The dopant concentration of the highly doped silicon layer is higher than the dopant concentration of the semiconductor substrate. The dopant deposited in situ, in the silicon layer, is for example boron, aluminum or gallium.

The deposition of the highly doped silicon layer of the first polarity can also take place in two steps, instead of in one. In this case, initially undoped silicon is deposited, and a dopant is subsequently introduced. The dopant is introduced, for example, by means of ion implantation or the application of a dopant source and the subsequent diffusion by means of a thermal process or laser diffusion. The dopant is, for example, boron, aluminum or gallium. The diffusion can also take place only at a later point in time. For example, the method can also comprise a later step of introducing a further dopant. In this case, the diffusion of the dopants can take place simultaneously with the diffusion of the second dopant in a common thermal process.

According to one embodiment, it is provided for a dielectric layer to be applied to the back side. The dielectric layer comprises, for example, silicon nitride, silicon oxide, silicon carbide or aluminum oxide. The dielectric layer serves as what is known as a diffusion barrier against a dopant to be applied later, for example phosphorus, and has etch-resistant properties against a wet-chemical solution to be applied later. The dielectric layer has, for example, a greater thickness than the first passivation layer, preferably a thickness of more than 4 nm.

According to one embodiment, it is provided that, by locally removing the dielectric layer and the highly doped silicon layer of the first polarity and the first passivation layer on the back side, base regions of the semiconductor substrate on the back side are exposed. The individual layers are removed, for example, at least in part by laser irradiation.

According to one embodiment, it is provided for a part of the semiconductor substrate to be locally removed in the base regions of the semiconductor substrate, on the back side. This can also be achieved by laser irradiation.

According to one embodiment, it is provided for the exposing of the base regions of the semiconductor substrate on the back side to comprise etching the highly doped silicon layer of the first polarity and/or the first passivation layer and/or a part of the semiconductor substrate, locally in the base regions. For example, it can be provided for a wet-chemical solution to etch the highly doped silicon layer, the first passivation layer and a part of the semiconductor substrate at the previously laser-irradiated base regions. Alternatively, it can be provided for the wet-chemical solution to etch only the highly doped silicon layer or only a part of the semiconductor substrate. In this case, the other layers, for example the first passivation layer or the highly doped silicon layer, are removed by laser irradiation. Advantageously, a highly doped silicon layer, optionally deposited on the front side of the semiconductor substrate, and/or a passivation layer deposited on the front side of the semiconductor substrate, can also be etched by the wet chemical solution.

It can be provided for the etching to comprise isotropic etching for polishing regions, and/or for the etching to comprise anisotropic etching for texturing regions. For example, the base regions can be polished by isotropic etching using a wet-chemical solution on the back side. Alternatively, the base regions can be textured by anisotropic etching using a wet-chemical solution on the back side. It can also be advantageous if the front side is textured by anisotropic etching using a wet-chemical solution. Different wet-chemical solutions can be used for removing the different layers and optionally texturing and/or polishing the surfaces.

According to one embodiment, it is provided for the method to comprise a step of attaching a precursor layer comprising a dopant, in particular phosphorus, on the back side or on the back side and on the front side. The precursor layer can be deposited on the front side and on the back side in one method step or in different method steps. The precursor layers on the front and back sides can have the same or different properties. The precursor layer is a layer comprising a dopant of a second polarity, in particular a phosphosilicate glass layer, PSG. The precursor layer is applied in particular on the dielectric layer and on, in particular, the wet-chemical etched regions on the back side and on the front side. If the highly doped silicon layer of the first polarity is a p-type silicon layer, the dopant in the precursor layer for doping the silicon according to the second polarity is, for example, phosphorus. In order to apply the precursor layer, a furnace diffusion process can be carried out, for example, in which a phosphosilicate glass layer grows on the back side and on the front side on the previously etched regions. In particular cases, the PSG layer may also grow on the dielectric layer on the back side. The furnace diffusion process can be carried out such that a high proportion of phosphorus is contained in the phosphosilicate glass layer after the furnace diffusion process. In a further embodiment, the precursor layer, for example PSG, can be deposited, for example by means of PECVD, LPCVD or APCVD.

According to one embodiment, it is provided that, by means of a high-temperature step, in which the dopant diffuses from the precursor layer into the base regions on the back side and/or into the surface of the front side, the doping in the base regions on the back side is increased and/or a doped region is produced on the front side. The dopant dopes the base regions on the back side according to a second polarity, counter to the first polarity of the highly doped silicon layer, so that doped base regions are created. The doped base regions on the back side have a higher dopant concentration than the dopant concentration of the semiconductor substrate. On the back side, the dopant does not diffuse from the precursor layer into the highly doped silicon layer, since the dielectric layer serves as a diffusion barrier against the dopant from the precursor layer. On the front side, a doped region is produced on the front side by the doping of the surface according to the second polarity. The dopant concentration of the doped region on the front side is higher than the dopant concentration of the semiconductor substrate. The high-temperature step is, for example, the furnace diffusion step for applying the precursor layer. Alternatively, it can also be an additional high-temperature step.

The high-temperature step can, for example, be carried out such that only part of the second dopant diffuses from the precursor layer into the base regions on the back side.

According to one embodiment, it is provided that a highly doped base region is produced within the base regions on the back side, by locally increasing the dopant concentration, in particular by laser irradiation. As a result of the laser irradiation, the surface is locally heated and melted on the back side in the irradiated regions. Further dopant from the precursor layer diffuses into the surface in the irradiated regions and, after cooling and recrystallization, further dopes the irradiated region according to the second polarity, such that highly doped base regions are produced. The dopant concentration in the highly doped base regions is significantly higher than the dopant concentration of the semiconductor substrate, higher than that of the doped base regions on the back side, and higher than that in the doped region on the front side.

By generating the highly doped base regions by laser irradiation, a doping, in particular optimized to the front side of the solar cell, can advantageously be created in the preceding step of furnace diffusion. The front side is ideally doped lower than the base regions on the back side. If the front and back sides are doped in only one common process step, a compromise of doping is required. This disadvantage is overcome by creating the highly doped base regions on the back side by means of laser irradiation.

According to one embodiment, it is provided that the method comprises a step of removing the precursor layer, in particular phosphosilicate glass, from the front side and/or from the back side. The removal takes place, for example, in a wet-chemical cleaning step. Advantageously, the wet-chemical cleaning step or a further post-chemical cleaning step also removes remaining residues of the dielectric layer from the highly doped silicon layer.

According to one embodiment, it is provided that the method comprises a step for applying a second passivation layer on the back side and/or a third passivation layer on the front side. A passivation layer comprises, for example, silicon dioxide, silicon nitride, aluminum oxide, or a layer stack of two or more dielectric layers. In this case, the thickness, refractive index and composition of the passivation layer on the back side can differ from the thickness, refractive index and composition of the passivation layer on the front side. The thicknesses of the passivation layers are advantageously optimized such that the reflection is reduced on the front side and increased on the back side. The second and/or third passivation layer advantageously has a greater thickness than the first passivation layer. The thickness of the second and/or third passivation layer is advantageously greater than 4 nm.

According to one embodiment, it is provided that the method comprises a step for selectively removing the second passivation layer on the back side. The passivation layer can be removed locally, for example by laser irradiation.

According to one embodiment, it is provided that the method comprises a step for applying electrodes of a first polarity and electrodes of a second polarity on the back side of the solar cell. The electrodes can be applied, for example, by means of screen printing, vapor deposition, sputtering or galvanic deposition of one or more metals or other conductive layers. The electrodes can comprise, for example, silver paste, silver/aluminum paste, aluminum paste or pure aluminum, copper, tin, palladium, silver, titanium, nickel or layer stacks or alloys of the mentioned metals, or other conductive layers, in particular conductive polymers or oxides, or a combination of such layers with metals. The composition and the deposition process of the electrodes can differ for the electrodes of the two polarities. Preferably, the electrodes of the second polarity contact only the highly doped base regions and not the doped base regions.

This invention also relates to a solar cell and a method for producing a solar cell, in which the described polarities each include an opposite polarity to the described polarities. The solar cell then comprises, for example, a p-type doped base, correspondingly an n-type doped emitter, and in turn a p-type base doping of the surfaces.

Further features, possible applications and advantages of the invention emerge from the following description of embodiments of the invention, which are shown in the figures of the drawing. In this case, all of the features described or shown form the subject matter of the invention per se or in any combination, irrespective of their grouping in the claims or their dependency reference, and irrespective of their wording or representation in the description or in the drawings.

### BRIEF DESCRIPTION OF THE DRAWINGS

In the drawings:

FIG. 1 is a schematic view of a detail of a solar cell according to the invention, and

FIGS. 2a, 2b, 2c, 2d, 2e, 2f, 2g and 2h show a solar cell according to FIG. 1 in various steps of a method for producing the solar cell.

### DETAILED DESCRIPTION

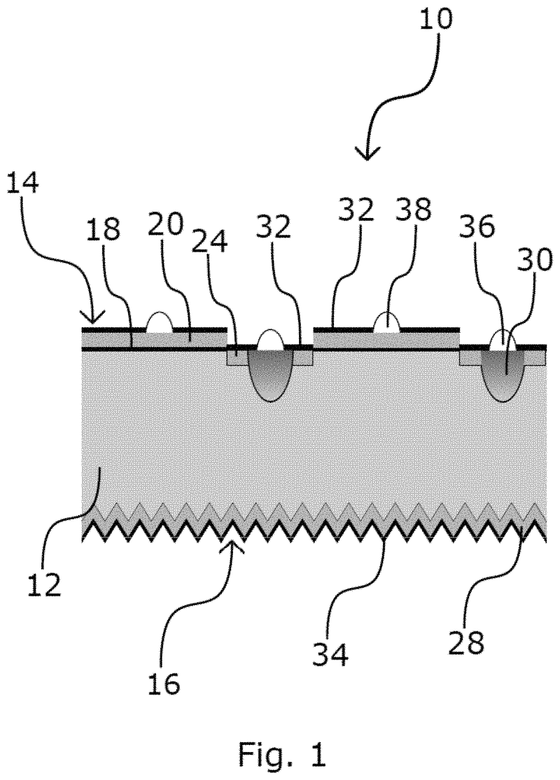

FIG. 1 shows a detail of a solar cell 10 comprising a semiconductor substrate 12, in particular a silicon wafer, a back side 14, and a front side 16 which faces the sun during operation of the solar cell. The silicon wafer 12 can be either n- or p-type doped. The solar cell 10 is explained by way of example on the basis of an n-type doping of the silicon wafer 12, of the “base”.

The front side 16 of the solar cell 10 is preferably textured. The back side 14 of the solar cell 10 can be polished or textured, in particular in different regions.

A polycrystalline highly doped p-type silicon layer 20 is provided on the back side 14. This forms a first polarity having a first doping concentration on the back side 14. In the region of the highly doped p-type silicon layer 20, a first passivation layer 18, in particular comprising silicon dioxide, passivates the surface of the silicon wafer 12. Furthermore, doped base regions 24 of a second polarity opposed to the first polarity are provided. The doped base regions 24 on the back side 14 have the same polarity but a higher dopant concentration compared with the semiconductor substrate 12.

A doped region 28 is located on the front side 16. The doped region 28 likewise has the same polarity but a higher dopant concentration compared with the semiconductor substrate 12.

Highly doped base regions 30 are formed within the doped base regions 24 on the back side. The highly doped base regions likewise have the second polarity, but a significantly higher dopant concentration than the semiconductor substrate 12, than the doped base regions 24 and than the doped region 28.

The solar cell 10 further comprises a second passivation layer 32 on the back side 14 and a third passivation layer 34 on the front side 16. The passivation layer 32 at least partially covers the highly doped silicon layer 20, the doped base regions 24 and the highly doped base regions 30, in the regions not contacted by electrodes 36, 38. The second passivation layer 32, for example formed by a dielectric layer or layer stack, preferably has a greater thickness than the first passivation layer 18, preferably a thickness of more than 4 nm. The second passivation layer 32 can consist, for example, of silicon dioxide, silicon nitride or aluminum oxide, or of a layer stack of these layers. The thicknesses and refractive indices of the passivation layer 32 can be optimized such that as much electromagnetic radiation as possible which was not absorbed by the solar cell is reflected back into the solar cell at the back side.

The third passivation layer 34 on the front side 16 preferably also has a greater thickness than the first passivation layer 18, preferably a thickness of more than 4 nm. The third passivation layer 34 can consist, for example, of silicon dioxide, silicon nitride or aluminum oxide, or of a layer stack of these layers. The thicknesses and refractive indices of the third passivation layer 34 can be optimized in such a way that as much electromagnetic radiation as possible that is incident on the front side 16 is not reflected and absorbed.

The solar cell 10 comprises, on the back side 14, electrodes 36 of a first polarity and electrodes 38 of a second polarity. The electrodes 36 of the first polarity contact the highly doped silicon layer 20 of the first polarity deposited on the first passivation layer 18. Advantageously, the electrodes 36 do not penetrate the first passivation layer 18. However, it may happen that the electrodes 36 partially penetrate the first passivation layer 18 and contact the semiconductor substrate 12. The electrodes 38 of the second polarity contacted the semiconductor substrate 12 directly electrically and mechanically in the doped base regions 24, preferably only in the highly doped regions 30 of the doped base regions 24.

Regions not contacted by the electrodes 36, 38 can either be covered and passivated by the layer stack of the first passivation layer 18 and highly doped silicon layer 20 of the first polarity, or by the second passivation layer 32 in the doped base regions 24 and highly doped base regions 30. The second passivation layer 32 can also cover the highly doped silicon layer 20 in the non-contacted regions.

Preferably, the surface electrically contacted by the electrodes 36 of the second polarity corresponds to the surfaces of the highly doped base regions 30 of the second polarity.

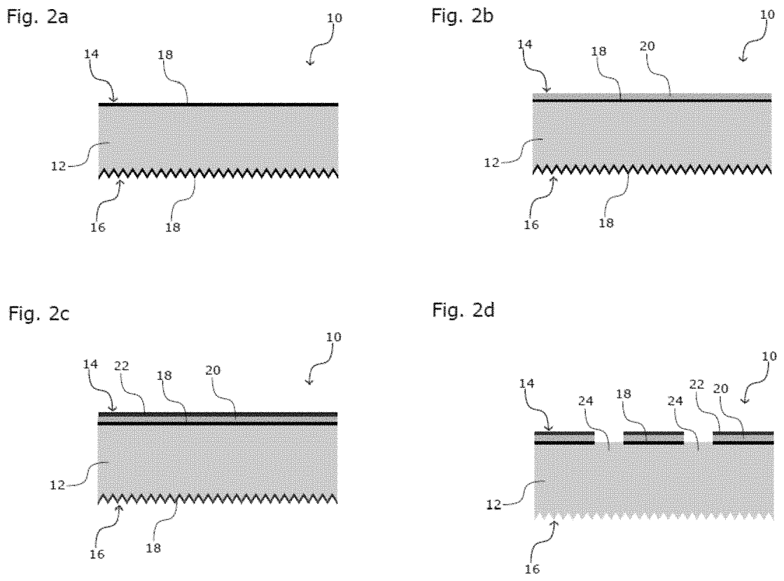

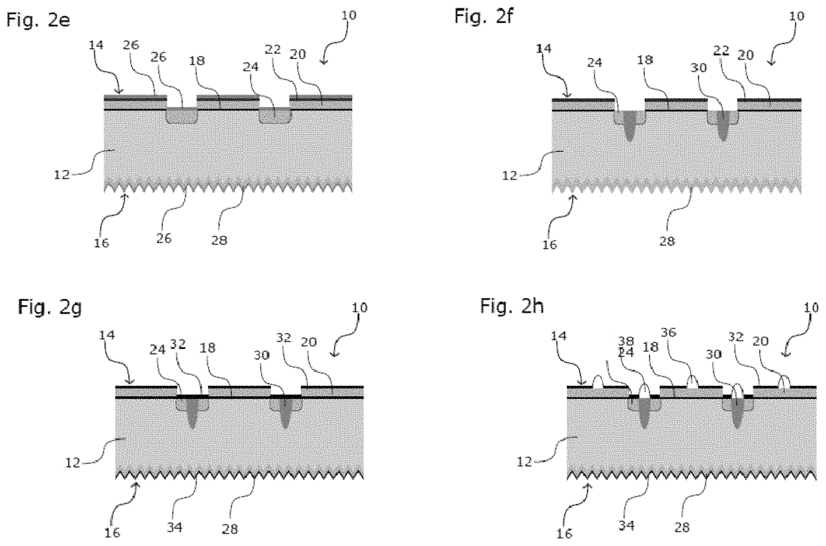

The production process of the solar cell 10 is explained below with reference to FIGS. 2a to 2h. FIGS. 2a to 2h illustrate the process sequence for the manufacture of a back-contact solar cell 10 having a passivated contact in the region of the highly doped silicon layer 20 and a diffused contact in the region of the highly doped base regions 30. The semiconductor substrate 12 can be n- or p-type doped, as a starting material. The process sequence is explained on the basis of an n-type doping of the wafer, of the “base”.

FIG. 2a shows the initial form of the silicon wafer 12 having a polished back side 14 and a textured front side 16. According to a further initial form (not shown), both the front and the back side can either be both polished or both textured. According to the embodiment shown, a first passivation layer 18, for example a silicon dioxide, having a thickness of preferably at most approximately 4 nm, is produced on the front side 16 and on the back side 14, for example in a thermal or wet-chemical process or by deposition. Alternatively, according to a further embodiment of the first passivation layer that is not shown, the deposition can take place only on the back side 14.

In a next step, cf. FIG. 2b, an, in particular full-surface, highly doped silicon layer 20 of a first polarity is deposited on the tunnel layer 18 on the back side 14. In the following, a p-type doping is assumed as the first polarity of the highly doped silicon layer. The deposition of the highly doped p-type silicon layer 20 can take place, for example, by means of plasma-enhanced chemical vapor deposition, PECVD, atmospheric chemical vapor deposition, APCVD, low pressure chemical vapor deposition (LPCVD) or cathode sputtering. The highly doped p-type silicon layer 20 has a thickness of approximately 50 nm to 400 nm. According to a further embodiment which is not shown, the deposition of the highly doped silicon layer can also take place on both sides, on front and back sides.

The deposition of the highly doped p-type silicon layer 20 can take place in two steps instead of in one. In this case, the deposition of the p-type silicon layer 20 comprises the deposition of undoped silicon and subsequent introduction of a dopant. The dopant is introduced, for example, by means of furnace diffusion or laser diffusion from a doping source applied to the silicon layer, or by means of ion implantation. The dopant is, for example, boron, aluminum or gallium.

In a next step of the method, cf. FIG. 2c, a dielectric layer 22 is deposited on the back side 14, on the highly doped silicon layer 20. The layer deposition takes place only on the back side 14. A parasitic deposition on the front side 16 cannot be ruled out entirely. The dielectric layer 22 is deposited, for example, by PECVD, APCVD, LPCVD or PVD. The dielectric layer 22 has a greater thickness than the first passivation layer 18 and is thus thicker than 4 nm.

FIG. 2d shows a further method step of exposing base regions 24 of the semiconductor substrate 12 on the back side 14 by local removal of the dielectric layer 22, of the highly doped silicon layer 20 of the first polarity, and of the first passivation layer 18. Furthermore, the removal of the passivation layer 18 on the front side 16 is shown. In a further embodiment which is not shown, removal of a silicon layer on the front side 16 may also be necessary.

The exposure of the base regions 24 takes place, for example, by local removal of the dielectric layer 22 by laser irradiation. It is also conceivable that the second dielectric layer 22 is not completely removed.

The highly doped silicon layer 20, the first passivation layer 18, and optionally a part of the semiconductor substrate 12 can likewise be at least partially locally removed by laser irradiation.

Alternatively, the highly doped silicon layer 20 and/or the first passivation layer 18 can be partially etched, locally, by a wet-chemical solution. The dielectric layer 22 was advantageously selected such that the wet-chemical solution does not etch the dielectric layer 22, or etches it substantially more slowly than the highly doped silicon layer 20 and the first passivation layer 18. Depending on which layers have already been previously removed by laser irradiation, the wet-chemical solution optionally also etches remaining residues of the dielectric layer 22, the first passivation layer 18 on the front side 16, and optionally a part of the semiconductor substrate on the front side 16 and the back side 14. Alternatively, the first passivation layer 18 can also serve as an etching barrier, such that the first passivation layer and the semiconductor substrate 12 are not etched. In the event that the highly doped silicon layer is also located on the front side 16, this is also etched in a further embodiment (not shown).

It can be provided for the etching to comprise isotropic etching for polishing regions, and/or for the etching to comprise anisotropic etching for texturing regions. For example, the base regions 24 can be polished by isotropic etching using a wet-chemical solution, on the back side 14. Alternatively, the base regions 24 can be textured by anisotropic etching using a wet-chemical solution, on the back side 14. It can also be advantageous if the front side 16 is textured by anisotropic etching using a wet-chemical solution. Different wet-chemical solutions can be used for removing and optionally texturing and/or polishing the different layers and surfaces.

FIG. 2e shows the deposition of a precursor layer 26 on the entire back side 14 and the entire front side 16 of the solar cell 10. The deposition on front side 16 and back side 14 takes place, for example, simultaneously. The precursor layers 26 on the front side 16 and the back side 14 can have different properties, for example with regard to the thickness or a dopant quantity contained in the precursor layer 26. On the back side, the precursor layer 26 on the different surfaces, the dielectric layer 22, or the exposed base region 24, can be deposited differently and thus have different properties. The precursor layer 26 is a layer comprising a dopant of a second polarity, in particular a phosphosilicate glass layer, PSG. In order to apply the precursor layer 26, for example a furnace diffusion process can be carried out, in which a phosphosilicate glass layer grows on the highly doped silicon layer 20, on the back side 14 and on the front side 16. The furnace diffusion process can be carried out such that a high proportion of phosphorus is contained in the phosphosilicate glass layer after the furnace diffusion process. Alternatively, the precursor layer 26, for example PSG, can be deposited, for example by means of PECVD, LPCVD or APCVD.

In a high-temperature step, in which the dopant diffuses from the precursor layer 26 into the base regions 24 on the back side 14 and/or into the surface of the front side 16, the doping in the base regions 24 on the back side 14 is increased and a doped region 28 is produced on the front side 16. The dopant dopes the base regions 24 on the back side 14 according to a second polarity, opposite to the first polarity of the highly doped silicon layer 20, such that doped base regions 24 are generated. The doped base regions 24 on the back side 14 have a higher dopant concentration than the dopant concentration of the semiconductor substrate 12. On the back side 14, the dopant does not diffuse from the precursor layer 26, or only in small amounts, into the highly doped silicon layer 20, since the dielectric layer 22 serves as a diffusion barrier against the dopant from the precursor layer 26. On the front side 16, the doped region 28 on the front side 16 is created by the doping of the surface according to the second polarity. The dopant concentration of the doped region 28 on the front side 16 is higher than the dopant concentration of the semiconductor substrate 12. The high-temperature step is, for example, the furnace diffusion step for applying the precursor layer 26. Alternatively, it can also be an additional high-temperature step.

The high-temperature step can be carried out, for example, in such a way that only a part of the second dopant diffuses from the precursor layer into the base regions on the back side, such that a significant amount of dopant is then preferably still located in the precursor layer 26. The high-temperature step can also serve to activate the dopant in the highly doped layer 20.

FIG. 2f shows the creation of highly doped base regions 30 in the doped base regions 24 by locally increasing the dopant concentration, in particular by laser irradiation. As a result of the laser irradiation, the previously deposited precursor layer 26 melts or evaporates, and the surface on the back side is locally heated and melted in the irradiated regions. Further dopant from the precursor layer diffuses into the surface at the irradiated regions and, after cooling and recrystallization, further dopes the irradiated region according to the second polarity, such that the highly doped base regions 30 are produced. The dopant concentration in highly doped base regions 30 is significantly higher than the dopant concentration of the semiconductor substrate 12, the doped base regions 24, and the doped region 28 on the front side 16. By suitable selection of the laser parameters, locally selectively differently highly doped portions can also be produced in the highly doped base regions 30.

Furthermore, it is provided that, in particular, remaining residues of the precursor layer 26 are removed from the front side 16 and from the back side 14. The removal takes place after the laser irradiation, for example in a wet-chemical cleaning step. Advantageously, remaining residues of the dielectric layer 22 are also removed from the highly doped silicon layer 20 by the wet-chemical cleaning step or by a further post-chemical cleaning step.

The method further comprises a step for applying a second passivation layer 32 on the back side 14 and a third passivation layer 34 on the front side 16, cf. FIG. 2g. The passivation layers 32, 34 comprise, for example, silicon dioxide, silicon nitride, aluminum oxide or a layer stack of two or more dielectric layers. In this case, the thickness, refractive index and composition of the second passivation layer 32 on the back side 14 can differ from the thickness, refractive index and composition of the third passivation layer 34 on the front side 16. The thicknesses of the passivation layers 32, 34 are advantageously optimized such that the reflection is reduced on the front side 16 and increased on the back side 14. The passivation layers 32, 34 advantageously have a greater thickness than the first passivation layer 18. The thickness of the second passivation layer 32 is advantageously greater than 4 nm. The high-temperature step for the growth of the thermal silicon dioxide, of the passivation layers 32, 34, can also serve to activate the dopant in the highly doped layer 20.

The method further comprises a step for applying electrodes 36 of a first polarity and electrodes 38 of a second polarity on the back side 14 of the solar cell 10, cf. FIG. 2h. The electrodes 36, 38 can be applied, for example, by means of screen printing, vapor deposition, sputtering or galvanic deposition of one or more metals or other conductive layers. The electrodes 36, 38 can comprise, for example, silver paste, silver/aluminum paste, aluminum paste or pure aluminum, copper, tin, palladium, silver, titanium, nickel, or layer stacks or alloys of the mentioned metals, or other conductive layers, in particular conductive polymers or oxides, or a combination of such layers with metals. The composition and the deposition process of the electrodes 36, 38 can differ for the electrodes 36, 38 of the two polarities. The electrodes 36, 38 can locally penetrate the passivation layer 32, in particular in a high-temperature step after the screen printing, and, depending on the polarity of the electrodes 36, 38, contact either a doped base region 24, the highly doped silicon layer 20, or a highly doped base region 30. Preferably, the electrodes 38 of the second polarity only contact the highly doped base regions 30 and not the doped base regions 24.

Optionally, prior to applying the electrodes 36, 38, the passivation layer 32 can be selectively removed, for example by laser irradiation, such that the electrodes directly contact the highly doped silicon layer 20 or the locally highly doped base regions 30 exclusively in the selectively removed regions.

1.-17. (canceled)

18. A back-contact solar cell comprising a semiconductor substrate, in particular a silicon wafer, comprising a front side and a back side, the solar cell comprising electrodes of a first polarity and electrodes of a second polarity on the back side, the electrodes of the first polarity being arranged on a highly doped silicon layer of the first polarity, the highly doped silicon layer being arranged on a first passivation layer arranged on the semiconductor substrate, and the electrodes of the second polarity directly electrically and mechanically contacting the semiconductor substrate via highly doped base regions of the second polarity of the semiconductor substrate, characterized in that the highly doped base regions of the second polarity are formed within the doped base regions of the second polarity on the back side of the solar cell, a dopant concentration in the highly doped base regions being higher than a dopant concentration in the doped base regions, and the dopant concentration in the highly doped base regions being higher than a dopant concentration of a doped region on the front side of the solar cell.

19. The back-contact solar cell according to claim 18, wherein a second passivation layer is arranged on surface regions of the back side not contacted by the electrodes of the first polarity and not by the electrodes of the second polarity, the second passivation layer being thicker than the first passivation layer.

20. A method for producing a back-contact solar cell according to claim 18, a semiconductor substrate of the solar cell comprising an, in particular polished or textured, back side and an, in particular textured, front side, the method comprising the following steps: applying a first passivation layer, in particular comprising silicon dioxide, to a surface of the back side; separation of an, in particular, full-coverage, highly doped silicon layer of a first polarity to the first passivation layer on the back side; applying a dielectric layer on the back side, exposing base regions of the semiconductor substrate on the back side by locally removing the dielectric layer, and the highly doped silicon layer of the first polarity and the first passivation layer on the back side; locally removing a portion of the semiconductor substrate in the base regions; characterized in that the method a step for attaching a precursor layer comprising a dopant, in particular phosphorous, on the back side and in that by a high temperature step, in which the dopant from the precursor layer diffuses into the base regions on the back side, the doping is increased in the base regions on the back side, and in that highly doped base regions are generated by locally increasing the dopant concentration in the doped base regions on the back side.

21. The method according to claim 20, wherein the first passivation layer is also applied to a surface of the front side.

22. The method according to claim 20, wherein exposing the base regions of the semiconductor substrate on the back side comprises etching of the highly doped silicon layer of the first polarity and/or etching of the first passivation layer and/or etching of a portion of the semiconductor substrate, locally in the base regions.

23. The method according to claim 22, wherein the etching comprises isotropic etching for polishing regions, and/or the etching comprises anisotropic etching for texturing regions.

24. The method according to claim 22, wherein the step for attaching a precursor layer comprising a dopant, in particular phosphorus, on the back side, also comprises attaching the precursor layer on the front side.

25. The method according to claim 24, wherein, by means of the high-temperature step in which the dopant diffuses from the precursor layer into the base regions on the back side, the dopant from the precursor layer diffuses into the surface of the front side and a doped region is produced on the front side.

26. The method according to claim 22, wherein the highly doped base regions are produced within the doped base regions on the back side by locally increasing the dopant concentration by laser irradiation.

27. The method according to claim 22, wherein the method comprises a step of removing the precursor layer, in particular phosphorus silicate glass, from the front side and/or from the back side.

28. The method according to claim 22, wherein the method comprises a step of applying a second passivation layer on the back side and/or a third passivation layer on the front side.

29. The method according to claim 28, wherein the method comprises a step of selectively removing the second passivation layer on the back side.

30. The method according to claim 22, wherein the method comprises a step of applying electrodes of a first polarity and electrodes of a second polarity on the back side of the solar cell.
